(19) United States
(12) Patent Application Publication
(10) Pub. No.: US 2011/0246857 A1
(43) Pub. Date: Oct. 6, 2011

(54) MEMORY SYSTEM AND METHOD

(75) Inventors: Seung-Jun Bae, Hwaseong-si (KR); Kwang-Il Park, Yongin-si (KR); Young-Soo Sohn, Seoul (KR); Young-Hyun Jun, Seoul (KR); Joo-Sun Choi, Yongin-si (KR); Tae-Young Oh, Seoul (KR)

(73) Assignee: SAMSUNG ELECTRONICS CO., LTD., Suwon-si (KR)

(21) Appl. No.: 13/078,364

(22) Filed: Apr. 1, 2011

Related U.S. Application Data
(60) Provisional application No. 61/320,567, filed on Apr. 2, 2010.

(30) Foreign Application Priority Data
Sep. 8, 2010 (KR) 10-2010-0087753

(51) Int. Cl. H03M 13/09; H03M 13/05; G06F 11/10

(52) U.S. Cl. 714/763; 714/807; 714/E11.034

(57) ABSTRACT

A memory system includes a memory controller and a memory device. The memory device exchanges data through a first channel with the memory controller, exchanges a first cyclic redundancy check (CRC) code associated with the data through a second channel with the memory controller, and receives a command/address packet including a second CRC code associated with a command/address from the memory controller through a third channel.

### CROSS-REFERENCE TO RELATED APPLICATION(S)

This US non-provisional application claims the benefit of priority under 35 USC §119 to U.S. Provisional Application No. 61/320,567 filed on Apr. 2, 2010 in the USPTO, and Korean Patent Application No. 10-2010-0087753 filed on Sep. 8, 2010 in the Korean Intellectual Property Office (KIPO), the contents of which applications are herein incorporated by reference in their entirety.

### BACKGROUND

1. Technical Field

Exemplary embodiments relate to semiconductor devices, and more particularly to memory systems.

2. Description of the Related Art

As transmission speed of data between semiconductor chips increases, transmitted data are increasingly likely to include errors. Recently, various methods have been proposed for detecting errors included when data are transmitted between semiconductor chips. Since transmission speed of data between semiconductor chips continues to increase, there is need for new approaches to handling errors.

### SUMMARY

Accordingly, the inventive concept is provided to substantially obviate one or more problems due to limitations and disadvantages of the related art.

Some exemplary embodiments provide a memory system capable of providing efficient error handling or coverage.

According to one aspect, the inventive concept is directed to a memory system which includes a memory controller and a memory device. The memory device exchanges data with the memory controller through a first channel, exchanges a first cyclic redundancy check (CRC) code associated with the data with the memory controller through a second channel, and receives from the memory controller through a third channel a command/address packet including a second CRC code associated with a command/address.

In some embodiments, the first, second and third channels may be separate from each other.

In some embodiments, the command/address packet may further include the command/address.

In some embodiments, the data may be exchanged between the memory controller and the memory device in a packet format.

In some embodiments, the memory controller may include a first CRC circuit, a second CRC circuit and a serializer. The first CRC circuit receives read data, generates a read CRC code associated with the read data, and generates a decision signal based on write data and a write CRC code associated with the write data. The second CRC circuit may generate the second CRC code in response to the command/address. The serializer may serialize or packetize the command/address and the second CRC code to provide the command/address packet.

The first CRC circuit may include a first CRC generator, a second CRC generator and a comparing circuit. The first CRC generator may generate the write CRC code based on the write data. The second CRC generator may generate a local read CRC code associated with the read data based on the read data. The comparing circuit may compare the read CRC code and the local read CRC code to provide the decision signal.

In some embodiments, the memory device may include a first CRC circuit, a deserializer and a second CRC circuit. The first CRC circuit may generate the read CRC code associated with read data based on the read data, generate a first decision signal based on write data and a write CRC code associated with the write data, and provide the first decision signal to a memory core unit. The deserializer may separate the command/address packet into the command/address and the second CRC code. The second CRC circuit may generate a second decision signal based on the command/address, and provide the second decision signal to the memory core unit.

The first CRC circuit may include a first CRC generator, a second CRC generator and a comparing circuit. The first CRC generator may generate the read CRC code based on the read data. The second CRC generator may generate a local write CRC code associated with the write data based on the write data. The comparing circuit may compare the read CRC code and the local write CRC code to provide the first decision signal.

The second CRC circuit may include a CRC generator and a comparing circuit. The CRC generator may generate a local second CRC code based on the command/address packet. The comparing circuit may compare the local second CRC code and the second CRC code to provide the second decision signal.

In some embodiments, one bit of the first CRC code may correspond to a plurality of bits of the data.

According to another aspect, the inventive concept is directed to a memory system which includes a memory controller and a memory device. The memory device exchanges data with the memory controller through differential signaling. The memory device may include a memory cell array and an error check and correction (ECC) circuit. The memory cell array may include a normal cell array for storing the data and an ECC cell array for storing an ECC code associated with the data. The ECC circuit may correct errors in the data stored in the normal cell array using the ECC code.

The memory system may further include an input/output (I/O) circuit. The I/O circuit, connected to the ECC circuit, may provide corrected data from the ECC circuit to the memory controller through the differential signaling.

The ECC circuit may include an encoder and a decoder. The encoder may encode write data, provide the write data to the normal cell array, and provide the ECC code to the ECC cell array. The decoder may decode read data, correct errors in the read data, and provide corrected read data to the I/O circuit.

The decoder may include an error detector which determines whether the read data have errors to provide a decision signal, and an error corrector which corrects the errors in the read data to provide the corrected read data to the I/O circuit, in response to the decision signal.

In some embodiments, the I/O circuit may include an input buffer which selects the data between the data and inverted data to provide the data as the write data to the ECC circuit, and an output buffer which provides the data and the inverted data based on the read data.

The input buffer may include a selection circuit that selects the data between the data and the inverted data in response to a selection signal and a latch circuit that latches the data to provide the write data.

The output buffer may include a first latch circuit that latches the read data to provide the data, a data inversion unit that inverts the data and a second latch circuit that latches an output of the data inversion unit to provide the inverted data.

In some embodiments, the memory cell array may be single-ended connected to the ECC circuit.

In some embodiments, the ECC circuit may single-ended connected to the I/O circuit.

According to another aspect, the inventive concept is directed to a memory system comprising: a memory controller and a memory device. The memory device is configured to exchange data with the memory controller through a first channel, configured to exchange a first cyclic redundancy check (CRC) code associated with the data with the memory controller through a second channel, and configured to receive from the memory controller through a third channel a command/address packet including a second CRC code associated with a command/address. The memory controller comprises: a first CRC circuit configured to receive read data, configured to generate a read CRC code associated with the read data, and configured to generate a decision signal based on write data and a write CRC code associated with the write data; a second CRC circuit configured to generate the second CRC code in response to the command/address; and a serializer configured to packetize the command/address and the second CRC code to provide a command/address packet. The memory device comprises: a third CRC circuit configured to generate the read CRC code associated with read data based on the read data, configured to generate a second decision signal based on write data and a write CRC code associated with the write data, and configured to provide the second decision signal to a memory core unit; a deserializer configured to separate the command/address packet into the command/address and the second CRC code; and a fourth CRC circuit configured to generate a third decision signal based on the command/address, and configured to provide the third decision signal to the memory core unit.

In some embodiments, the first CRC circuit comprises: a first CRC generator configured to generate the write CRC code based on the write data; a second CRC generator configured to generate a local read CRC code associated with the read data based on the read data; and a comparing circuit configured to compare the read CRC code and the local read CRC code to provide the decision signal.

In some embodiments, the third CRC circuit comprises: a first CRC generator configured to generate the read CRC code based on the read data; a second CRC generator configured to generate a local write CRC code associated with the write data based on the write data; and a comparing circuit configured to compare the write CRC code and the local write CRC code to provide the first decision signal.

In some embodiments, the fourth CRC circuit comprises: a CRC generator configured to generate a local second CRC code based on the command/address packet; and a comparing circuit configured to compare the local second CRC code and the second CRC code to provide the second decision signal.

According to another aspect, the inventive concept is directed to a method of controlling a memory device with a memory controller. The method includes: exchanging data between the memory device and the memory controller through a first channel; exchanging a first cyclic redundancy check (CRC) code associated with the data between the memory device and the memory controller through a second channel; and receiving at the memory device from the memory controller through a third channel a command/address packet including a second CRC code associated with a command/address.

In some embodiments, the method further includes separating the first, second and third channels from each other.

In some embodiments, the command/address packet further includes the command/address.

In some embodiments, the data is exchanged between the memory controller and the memory device in a packet format.

In the memory system according to exemplary embodiments, transmission errors may be reduced while reducing the power consumption and not increasing the pin overhead.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. FIG. 1 is a schematic block diagram illustrating a memory system according to some exemplary embodiments of the inventive concept.

FIG. 2 is a schematic block diagram illustrating an example of the memory controller in FIG. 1 according to some exemplary embodiments of the inventive concept.

FIG. 3 is a schematic block diagram illustrating an example of the first CRC circuit in FIG. 2 according to some exemplary embodiments of the inventive concept.

FIG. 4 is a schematic block diagram illustrating an example of the memory device in FIG. 1 according to some exemplary embodiments of the inventive concept.

FIG. 5 is a schematic block diagram illustrating an example of the first CRC circuit in FIG. 4 according to some exemplary embodiments of the inventive concept.

FIG. 6 is a schematic block diagram illustrating an example of the second CRC circuit in FIG. 4 according to some exemplary embodiments of the inventive concept.

FIG. 7 contains a schematic block diagram which illustrates operation of the memory system of FIG. 1 in the write mode, according to some exemplary embodiments of the inventive concept.

FIG. 8 contains a schematic block diagram which illustrates operation of the memory system of FIG. 1 in the read mode, according to some exemplary embodiments of the inventive concept.

FIG. 9 is a schematic block diagram illustrating a memory system according to some exemplary embodiments of the inventive concept.

FIG. 10 is a schematic block diagram illustrating an example of the memory device in FIG. 9 according to some exemplary embodiments of the inventive concept.

FIG. 11 is a schematic block diagram illustrating an example of the ECC circuit in FIG. 10 according to some exemplary embodiments of the inventive concept.

FIG. 12 is a schematic block diagram illustrating an example of the input/output circuit in FIG. 10 according to some exemplary embodiments of the inventive concept.

### DETAILED DESCRIPTION OF THE EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this description will be thorough and complete, and will fully convey the inventive concept to those skilled in the art. In the drawings, the sizes and relative sizes of layers and regions may be exaggerated for clarity. Like numerals refer to like elements throughout.

It will be understood that, although the terms first, second, third, etc., may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements should be interpreted in a like fashion, e.g., “between” versus “directly between,” “adjacent” versus “directly adjacent,” etc.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a schematic block diagram illustrating a memory system according to some exemplary embodiments of the inventive concept.

Referring to FIG. 1, a memory system 10 includes a memory controller 100 and a memory device 200.

The memory controller 100 includes first through third pins 101, 103 and 105, and the memory device 200 includes first through third pins 201, 203 and 205. The term “pin” as used herein generally refers to electric interconnection to integrated circuits, and for example, the “pin” refers to different contact points on pads or the integrated circuits. Pins generally provide electrical contact points between integrated circuits and the exterior of the integrated circuits. In addition, the first pins 101 and 201 are for exchanging data DATA between the memory controller 100 and the memory device 200, the second pins 103 and 203 are for exchanging a first cyclic redundancy check (CRC) code CRC1 between the memory controller 100 and the memory device 200, and the third pins 105 and 205 are for transmitting a command/address packet CAP from the memory controller 100 to the memory device 200.

The first pins 101 and 201 are connected to each other through a first channel 20, the second pins 103 and 203 are connected to each other through a second channel 30, and the third pins 105 and 205 are connected to each other through a second channel 40. The first through third channels 20, 30 and 40 may be referred to as first through third lanes. In some embodiments, each of the first through third channels 20, 30 and 40 may include a plurality of lanes.

Although only one memory device 200 is illustrated in FIG. 1 as being connected to the memory controller 100, a plurality of memory devices and/or a memory module including a plurality of memory devices may be connected to the memory controller 100. When a plurality of memory devices are included in the memory module, each of the memory devices may be connected to the memory controller 100 through a respective data channel, a first CRC channel and command/ address channel.

The memory controller 100 controls data transmission to/from the memory device 200. In some embodiments, the memory controller 100 may be integrated in one die with one or more processors. In some embodiments, the memory controller 100 may be a part of a chipset of a computing system. In the memory system 10, the memory controller 100 exchanges data DATA with the memory device 200 through the first channel 20. The memory controller 100 exchanges the first CRC code CRC1 with the memory device 200 through the second channel 30, which is separate from the first channel 20. In addition, the memory controller 100 transmits the command/address packet CAP including a second CRC code CRC2 to the memory device 200 through the third channel 40 which is separate from the first and second channels 20 and 30. The memory device 200 may be, for example, a GDDR5 memory device.

In the memory system 10 of FIG. 1, the first CRC code CRC1 associated with the data DATA is transmitted/received through the second channel 30, which is separate from the first channel 20 through which the data DATA, which includes more bits than the command/address C/A, is transmitted/received. As a result, the memory system 10 has simple clocking, good CRC coverage and a simple frame format because additive latency is not required. In addition, since the second CRC code CRC2 associated with the command/address C/A, including fewer bits than the data DATA, is transmitted in the command/address packet CAP, interface errors between the data DATA and the command/address C/A may be detected, and reduction of bandwidth is minimized because pin overhead is not increased.

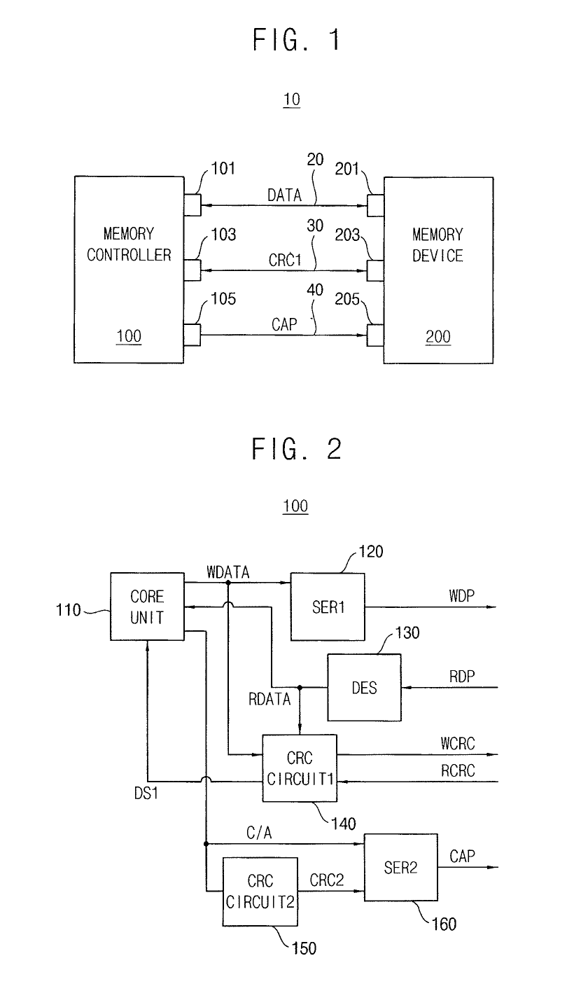

FIG. 2 is a schematic block diagram illustrating an example of the memory controller 100 in FIG. 1 according to some embodiments of the inventive concept.

Referring to FIG. 2, the memory controller 100 includes a core unit 110, a first serializer 120, a deserializer 130, a first CRC circuit 140, a second CRC circuit 150 and a second serializer 160.

Although not illustrated, the core unit 110 may include a data generator, a command generator, an address generator and a clock generator. The data generator may generate write data WDATA. The command generator may generate one or more commands. The address generator may generate one or more addresses. The clock generator may generate one or more clock signals. The command and the address may be merged into the command/address C/A signal.

The first serializer 120 serializes (packetizes) the write data WDATA from the core unit 110 to provide a write data packet WDP. In one particular exemplary embodiment, the first serializer 120 may serialize 8-bit data into one write data packet. The deserializer 130 deserializes a read data packet RDP from the memory device 200 into read data RDAT to provide the read data RDATA to the core unit 110 and the first CRC circuit 140. The first CRC circuit 140 generates a write CRC code WCRC associated with the write data WDATA based on the write data WDATA received by the first CRC unit 140 from the core unit 110 in a write mode. The write CRC code WCRC may include, for example, one bit per 8-bit write data WDATA. In addition, the first CRC circuit 140 provides a decision signal DS1 to the core unit 110 based on the read data RDATA and a read CRC code RCRC in a read mode. The second CRC circuit 150 generates a second CRC code CRC2 associated with the command/address C/A based on the command/address C/A received from the core unit 110. The second serializer 160 serializes (packetizes) the command/address C/A and the second CRC code CRC2 to provide the command/address packet CAP to the memory device 200.

The first serializer 120 and the deserializer 130 may be implemented separately as illustrated in FIG. 2. Alternatively, the first serializer 120 and the deserializer 130 may be implemented with one circuit which performs serialization in the write mode and performs deserialization in the read mode, in some exemplary embodiments.

When a length of the command/address packet CAP is the same as a length of the write data packet WDP or the read data packet RDP, the command/address packet CAP includes reserved bits which do not have information. When the second CRC code replaces the reserved bits in the command/address packet CAP, transmission errors, which may occur during the command/address being transmitted, may be checked and corrected without increasing the pin overhead.

The write data packet WDP and the read data packet RDP in FIG. 2 may be included in the data DATA in FIG. 1, and the write CRC code WCRC and the read CRC code RCRC in FIG. 2 may be included in the first CRC code CRC1 in FIG. 1.

The memory controller 100 may include an enable/disable logic (not illustrated) and the enable/disable logic may selectively enable the core unit 110, the first serializer 120, the deserializer 130, the first CRC circuit 140, the second CRC circuit 150 and the second serializer 160 according to an operation mode. For example, the enable/disable logic may enable the core unit 110, the first serializer 120, the first CRC circuit 140, the second CRC circuit 150 and the second serializer 160 in, for example, the write mode. Similarly, for example, the enable/disable logic may enable the core unit 110, the deserializer 130 and the first CRC circuit 140 in, for example, the read mode.

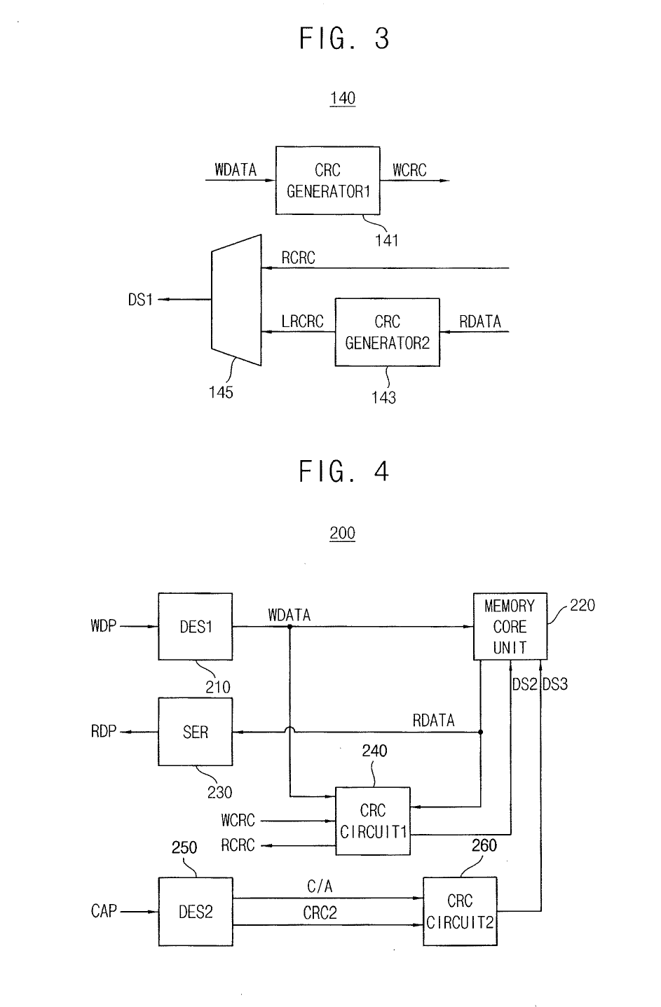

FIG. 3 is a schematic block diagram illustrating an example of the first CRC circuit 140 in FIG. 2, according to some embodiments of the inventive concept.

Referring to FIG. 3, the first CRC circuit 140 includes a first CRC generator 141, a second CRC generator 143 and a comparing circuit 145.

The first CRC generator 141 receives the write data WDATA and generates the write CRC code WCRC associated with the write data WDATA in the write mode. The second CRC generator 143 receives the read data RDATA and generates a local read CRC code LRCRC associated with the read data RDATA in the read mode. The comparing circuit 145 compares the read CRC code RCRC and the local read CRC code LRCRC to provide the decision signal DS1 to the core unit 110.

For example, when the read CRC code RCRC is the same as the local read CRC code LRCRC, the comparing circuit 145 provides the decision signal DS1 to the core unit 110 in a first logic level indicating that transmission errors are not in the read data RDATA. For example, when the read CRC code RCRC is different from the local read CRC code LRCRC, the comparing circuit 145 provides the decision signal DS1 to the core unit 110 in a second logic level indicating that transmission errors are in the read data RDATA. When the decision signal DS1 is in the second logic level, the core unit 110 may correct the errors in the read data RDATA and process the corrected read data RDATA.

FIG. 4 is a schematic block diagram illustrating an example of the memory device 200 in FIG. 1 according to some exemplary embodiments of the inventive concept.

Referring to FIG. 4, the memory device 200 includes a first deserializer 210, a memory core unit 220, a serializer 230, a first CRC circuit 240, a second deserializer 250 and a second CRC circuit 260.

The first deserializer 210 deserializes(divides) the write data packet WDP into the write data WDATA to provide the write data WDATA to the memory core unit 220 and the first CRC circuit 240. The serializer 230 serializes the read data RDATA from the memory core unit 220 into the read data packet RDP to provide the read data packet RDP to the memory controller 100. The first CRC circuit 240 provides a decision signal DS2 to the memory core unit 220 based on the write data WDATA and the write CRC code WCRC in the write mode, and generates the read CRC code RCRC based on the read data RDATA to provide the read CRC code RCRC to the memory controller 100 in the read mode. The second deserializer 250 deserializes the command/address packet CAP into the command address C/A and the second CRC code CRC2 to provide the command address C/A and the second CRC code CRC2 to the second CRC circuit 260.

The first deserializer 210 and the serializer 230 may be implemented separately as illustrated in FIG. 4. Alternatively, the first deserializer 210 and the serializer 230 may be implemented with one circuit which performs serialization in the write mode and performs deserialization in the read mode, in some embodiments of the inventive concept.

The memory device 200 may include an enable/disable logic (not illustrated), and the enable/disable logic may selectively enable the first deserializer 210, the memory core unit 220, the serializer 230, the first CRC circuit 240, the second deserializer 250 and the second CRC circuit 260 according to an operation mode. For example, the enable/disable logic may enable the first deserializer 210, the memory core unit 220, the first CRC circuit 240, the second deserializer 250 and the second CRC circuit 260 in the write mode. Similarly, for example, the enable/disable logic may enable the memory core unit 220, the serializer 230, and the first CRC circuit 240 in the read mode.

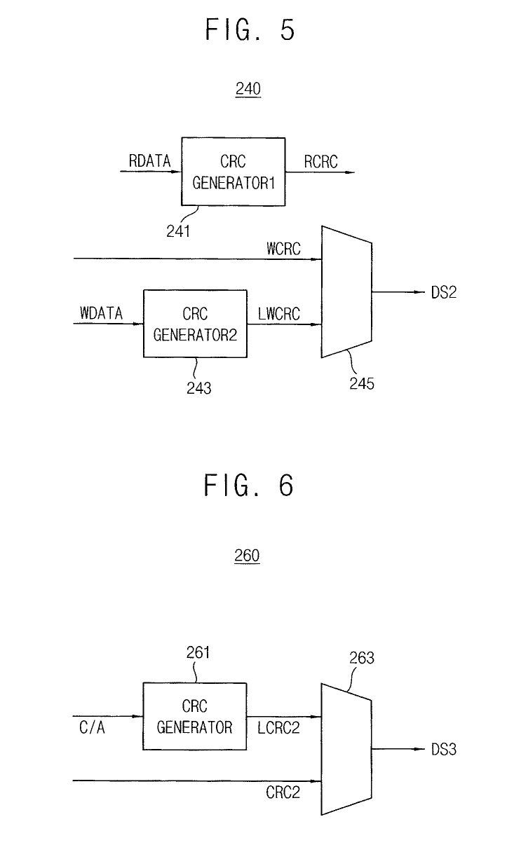

FIG. 5 is a schematic block diagram illustrating an example of the first CRC circuit 240 in FIG. 4 according to some embodiments of the inventive concept.

Referring to FIG. 5, the first CRC circuit 240 includes a first CRC generator 241, a second CRC generator 243 and a comparing circuit 245.

The first CRC generator 241 receives the read data RDATA and generates and forwards to the memory controller 100 the read CRC code RCRC based on the read data RDATA. The second CRC generator 243 receives the write data WDATA and generates a local write CRC code LWCRC associated with the write data WDATA. The comparing circuit 245 compares the write CRC code WCRC and the local write CRC code LWCRC to provide the decision signal DS2 to the memory core unit 220.

For example, when the write CRC code WCRC is the same as the local write CRC code LWCRC, the comparing circuit 245 provides the decision signal DS2 to the memory core unit 220 in a first logic level indicating that transmission errors are not in the write data WDATA. Also, for example, when the write CRC code WCRC is different from the local write CRC code LWCRC, the comparing circuit 245 provides the decision signal DS2 to the memory core unit 220 in a second logic level indicating that transmission errors are in the write data WDATA. When the decision signal DS2 is in the second logic level, the memory core unit 220 may correct the errors in the write data WDATA and store the corrected write data WDATA in a memory cell array (not illustrated).

FIG. 6 is a schematic block diagram illustrating an example of the second CRC circuit 260 in FIG. 4, according to some embodiments of the inventive concept.

Referring to FIG. 6, the second CRC circuit 260 includes a CRC generator 261 and a comparing circuit 263.

The CRC generator 261 receives the command/address C/A and generates a local second CRC code LCRC2 associated with the command/address C/A. The comparing circuit 263 compares the second CRC code CRC2 and the local second CRC code LCRC2 to provide a decision signal DS3 to the memory core unit 220. For example, when the second CRC code CRC2 is the same as the local second CRC code LCRC2, the comparing circuit 263 provides the decision signal DS3 to the memory core unit 220 in a first logic level indicating that transmission errors are not in the command/address C/A. Also, for example, when the second CRC code CRC2 is different from the local second CRC code LCRC2, the comparing circuit 263 provides the decision signal DS3 to the memory core unit 220 in a second logic level indicating that transmission errors are in the command/address C/A. When the decision signal DS3 is in the second logic level, the memory core unit 220 may correct the errors in the command/address C/A and operate according to the corrected command/address C/A.

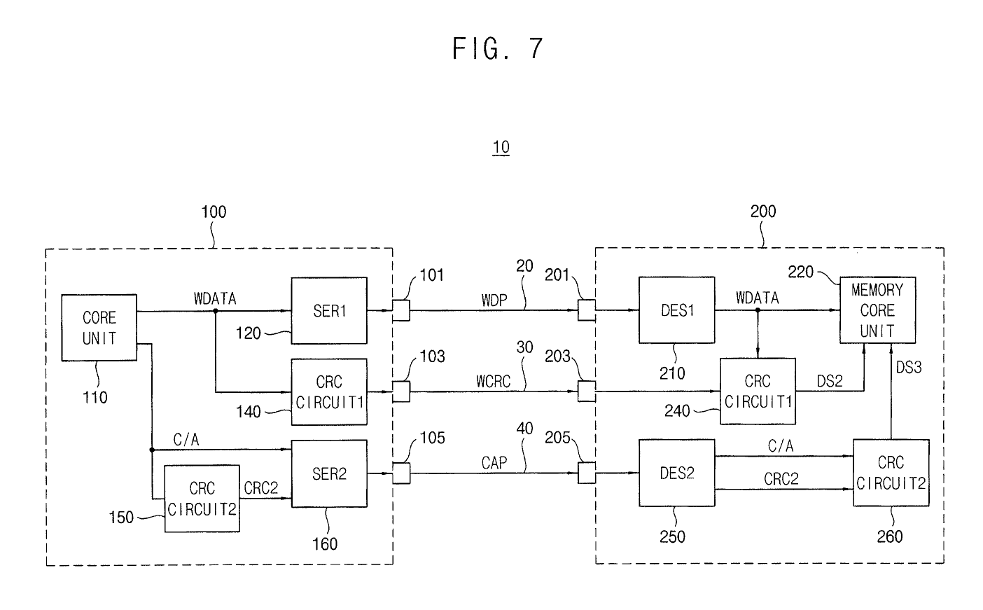

FIG. 7 contains a schematic block diagram which illustrates operation of the memory system of FIG. 1 in the write mode, according to some embodiments of the inventive concept.

Referring to FIG. 7, in the memory controller 100 in the write mode, the first serializer 120 serializes the write data WDAT into the write data packet WDP to be provided to the memory device 200 through the first channel 20. The first CRC circuit 140 provides the write CRC code WCRC based on the write data WDATA to the memory device 200 through the second channel 30. The second serializer 160 provides the command/address packet CAP based on the command/address C/A and the second CRC code CRC2 to the memory device 200 through the third channel 40. In the memory device 200 in the write mode, the first CRC circuit 240 provides the decision signal DS2 indicating whether transmission errors are in the write data WDATA to the memory core unit 220, based on the write data WDATA and the write CRC code WCRC, and second CRC circuit 260 provides the decision signal DS3 indicating whether transmission errors are in the command/address C/A to the memory core unit 220, based on the command/address C/A and the second CRC code CRC2.

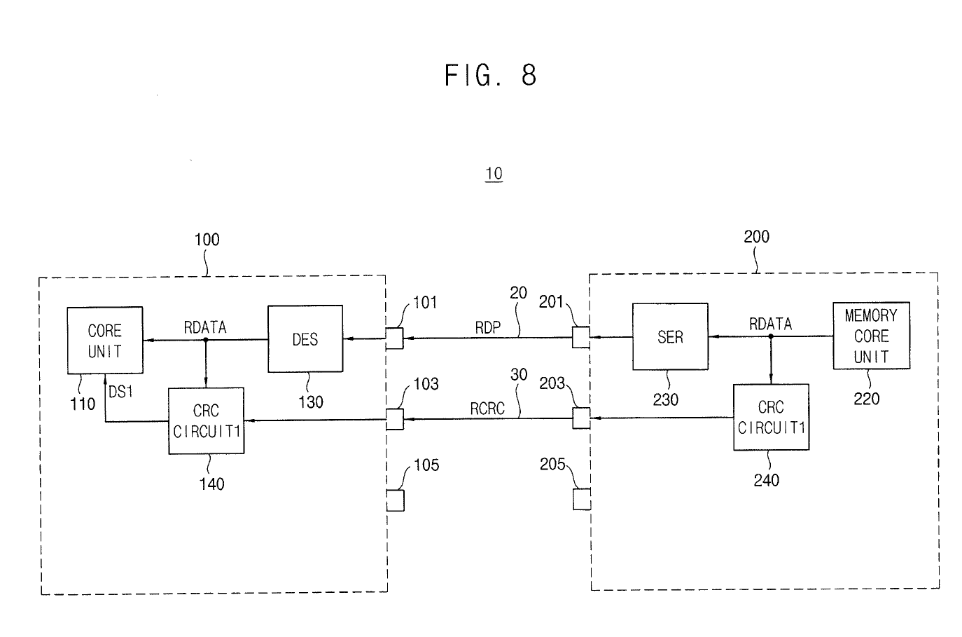

FIG. 8 contains a schematic block diagram which illustrates operation of the memory system of FIG. 1 in the read mode, according to some embodiments of the inventive concept.

Referring to FIG. 8, in the memory device 200 in the read mode, the serializer 230 serializes the read data RDATA into the read data packet RDP to be provided to the memory controller 100 through the first channel 20. The first CRC circuit 240 provides the read CRC code RCRC based on the read data RDATA to the memory controller 100 through the second channel 30. In the memory controller 100 in the read mode, the first CRC circuit 140 provides the decision signal DS1 indicating whether transmission errors are in the read data RDATA to the core unit 110, based on the read data RDATA and the read CRC code RCRC.

As described above with reference to FIGS. 1 through 8, in the memory system 10 according to some exemplary embodiments, since the first CRC code CRC1 associated with the data DATA is transmitted/received through the second channel 30 which is separate from the first channel 20 through which the data DATA including more bits than the command/address C/A is transmitted/received, the memory system 10 may have simple clocking, good CRC coverage and a simple frame format, because additive latency is not required. In addition, since the second CRC code CRC2 associated with the command/address C/A including less bits than the data DATA is transmitted in the command/address packet CAP, interface errors between the data DATA and the command/address C/A may be detected, and may minimize reduction of bandwidth because pin overhead is not increased.

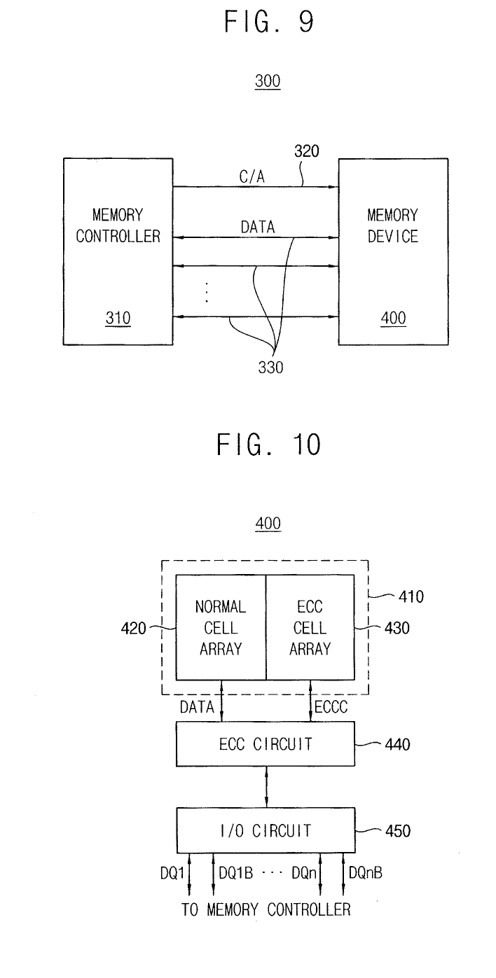

FIG. 9 is a schematic block diagram illustrating a memory system according to some exemplary embodiments of the inventive concept.

Referring to FIG. 9, a memory system 300 includes a memory controller 310 and a memory device 400.

The memory controller 310 is connected to the memory device 400 through interconnections 320 and 330. The memory controller 310 transmits command/address C/A to the memory device 400 through the interconnection (or a channel) 320. The memory controller 310 and the memory device 400 exchange data DATA through the interconnection (or channels) 330. The memory controller 310 and the memory device 400 exchange data DATA using differential signaling. The memory controller 310 controls data transmission to/from the memory device 400. In some embodiments, the memory controller 310 may be integrated in one die with one or more processors. In some embodiments, the memory controller 310 may be a part of a chipset of a computing system.

Although not illustrated, the memory controller 310 may include a data generator, a command generator, an address generator and a clock generator.

Although only one memory device 400 is illustrated as being connected to the memory controller 100 in FIG. 9, a plurality of memory devices and/or a memory module including a plurality of memory devices may be connected to the memory controller 310. When a plurality of memory devices are included in the memory module, the memory module may be a dual in-line memory module (DIMM). Each of the memory devices may be connected to the memory controller 310 through respective data transmission lines. In addition, each of the memory devices may be connected to command/address transmission lines in a tree configuration. In this case, data transmission lines may be connected to the memory controller and each of the memory devices using differential signaling. In some embodiments, each of the memory devices may be connected to command/address transmission lines in a fly-by daisy chain configuration.

In other embodiments, the memory module may be a registered dual in-line memory module (RDIMM). In this case, each of the memory devices may be connected to the memory controller 310 through respective data transmission lines. In addition, the memory devices may be connected to a command/address register, and the command/address register may be connected to the memory controller through a command/address transmission line. In this case, data transmission lines may be connected to the memory controller and each of the memory devices using differential signaling.

FIG. 10 is a schematic block diagram illustrating an example of the memory device in FIG. 9 according to some embodiments of the inventive concept.

Referring to FIG. 10, the memory device 400 may include a memory cell array 410, an error check and correction (ECC) circuit 440 and an input/output (I/O) circuit 450. Although not illustrated, the memory device 400 may further include a timing register, an address buffer, an address decoder and a command decoder.

The memory cell array 410 includes a normal cell array 420 for storing the data DATA and an ECC cell array 430 for storing an ECC code ECCC associated with the data DATA. The normal cell array 420 may include a plurality of normal cells, and the ECC cell array 430 may include a plurality of ECC cells. The ECC cells may be distributed in the memory cell array 410, and the ECC cells may be adjacent to the normal cells.

The ECC circuit 440 may correct errors by using the ECC code ECCC stored in the ECC cell array 430, when the errors occur in the normal cell array 420. The I/O circuit 450 is connected to the ECC circuit 440, and provides the data from the ECC circuit 440 to the memory controller 310 through differential signaling. That is, the I/O circuit 450 may provide the data DQ1˜DQn and inverted data DQ1B˜DQnB to the memory controller 310 via a plurality of transmission lines (channels).

The normal cells in the normal cell array 420 store data using capacitors, and thus errors may occur in data stored in the normal cell array 420 due to leakage current as time elapses. When the errors occur in the data stored in the normal cell array 420, the ECC circuit 440 may check and correct the errors using the ECC code ECCC stored in the ECC cell array 430. In addition, transmission errors may occur in transmitted data when the data is transmitted rapidly between the memory device 400 and the memory controller 310. According to some exemplary embodiments, such transmission errors may be reduced by providing the data DQ1˜DQn and the inverted data DQ1B˜DQnB to the memory controller 310 by using the differential signaling. The noise signals in the transmission errors in the data DQ1˜DQn and the inverted data DQ1B˜DQnB have reverse phase with respect to each other; thus, the noise may be cancelled. Therefore, the swing margin of the data DQ1˜DQn and the inverted data DQ1B˜DQnB may be reduced, and thus power consumption may be reduced.

In FIG. 10, the memory cell array 410 and the ECC circuit 440 may be connected to each other using a single-ended configuration, and the ECC circuit 440 and the I/O circuit 450 may also be connected to each other using a single-ended configuration.

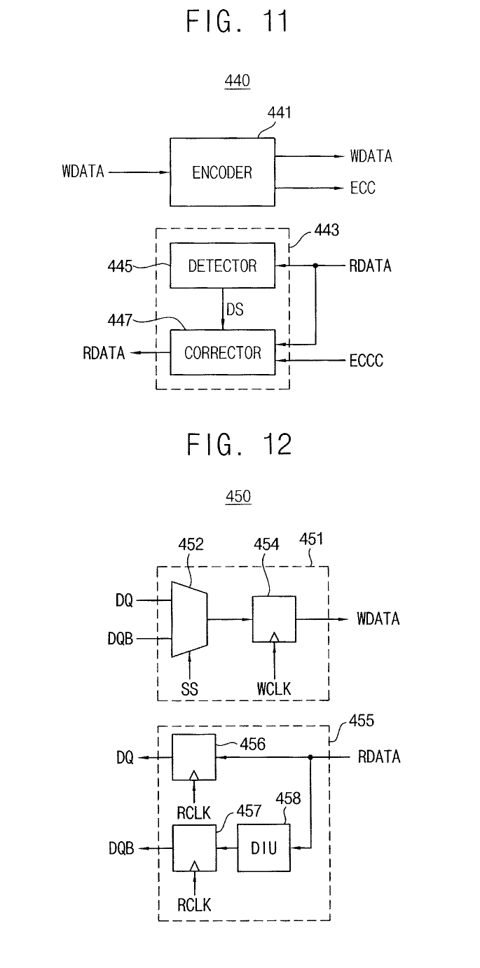

FIG. 11 is a schematic block diagram illustrating an example of the ECC circuit 440 in FIG. 10 according to some embodiments of the inventive concept.

Referring to FIG. 11, the ECC circuit 440 may include an encoder 441 and a decoder 443. The encoder 441 encodes the write data WDATA, generates the ECC code ECCC associated with the write data WDATA, provides the write data WDATA to the normal cell array 420 and provides the ECC code ECCC to the ECC cell array 430 in the write mode. The decoder 443 decodes the read data RDATA, corrects errors in the read data RDATA, and provides the corrected read data RDATA to the I/O circuit 450 in the read mode. The decoder 443 may include an error detector 445 and an error corrector 447. The error detector 445 provides a decision signal DS which indicates to the error corrector 447 whether errors are in the read data RDATA. The error corrector 447 corrects the errors in the read data RDATA to be provided to the I/O circuit 450 in response to the decision signal DS.

For example, when errors are in the read data RDATA, the error detector 445 provides the decision signal DS to the error corrector 447 in a first logic level. The error corrector 447 corrects the errors in the read data RDATA to be provided to the I/O circuit 450 using the ECC code ECCC, in response to the decision signal DS being in the first logic level. For example, when errors are not in the read data RDATA, the error detector 445 provides the decision signal DS in a second logic level to the error corrector 447. The error corrector 447 provides the read data RDATA to the I/O circuit 450 in response to the decision signal DS being in the second logic level.

FIG. 12 is a block diagram illustrating an example of the I/O circuit 450 in FIG. 10 according to some embodiments of the inventive concept.

Referring to FIG. 12, the I/O circuit 450 includes an input buffer 451 and an output buffer 455.

The input buffer 451 selects the data DQ of the data DQ and the inverted data DQB to provide the data DQ as the write data WDATA to the ECC circuit 440 in the write mode. The output buffer 455 provides the data DQ and the inverted data DQB externally based on the read data RDATA in the read mode.

The input buffer 451 may include a selection circuit 452 and a latch circuit 454. The selection circuit 452 selects the data DQ of the data DQ and the inverted data DQB in response to a selection signal SS. The latch circuit 454 latches the data DQ to provide the write data WDATA in synchronization with a write clock signal WCLK. The latch circuit 454 may be implemented with a D flip-flop.

The output buffer 455 may include a first latch circuit 456, a second latch circuit 457 and a data inversion unit (DIU) 458. The first latch circuit 456 latches the read data RDATA to provide the data DQ in synchronization with a read clock signal RCLK. The data inversion unit 455 inverts the read data RDATA to provide inverted read data. The second latch circuit 457 latches the inverted read data to provide the inverted data DQB in synchronization with the read clock signal RCLK. Since the first latch circuit 456 and the circuit latch circuit 457 operate in synchronization with the read clock signal RCLK, the data DQ and the inverted data DQB are output synchronously with respect to each other when delays occur in the data inversion unit 458.

As described above with reference to FIGS. 9 through 12, in the memory system according to some exemplary embodiments, errors occurring in the normal cell array may be corrected using the ECC circuit, and transmission errors may be reduced using differential signaling between the memory device and the memory controller.

Transmission errors may be reduced while reducing power consumption and not increasing pin overhead according to some exemplary embodiments.

The memory system according to the described embodiments may be used in various memory module and computing systems.

The foregoing is illustrative of exemplary embodiments and is not to be construed as limiting thereof. Although exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A memory system comprising:
a memory controller; and
a memory device configured to exchange data with the memory controller through a first channel, configured to exchange a first cyclic redundancy check (CRC) code associated with the data with the memory controller through a second channel, and configured to receive from the memory controller through a third channel a command/address packet including a second CRC code associated with a command/address.

3. The memory system of claim 1, wherein the first, second and third channels are separate from each other.

3. The memory system of claim 1, wherein the command/address packet further includes the command/address.

4. The memory system of claim 1, wherein the data is exchanged between the memory controller and the memory device in a packet format.

5. The memory system of claim 1, wherein the memory controller comprises:
a first CRC circuit configured to receive read data, configured to generate a read CRC code associated with the read data, and configured to generate a decision signal based on write data and a write CRC code associated with the write data;
a second CRC circuit configured to generate the second CRC code in response to the command/address; and
a serializer configured to packetize the command/address and the second CRC code to provide the command/address packet.

6. The memory system of claim 5, wherein the first CRC circuit comprises:
a first CRC generator configured to generate the write CRC code based on the write data;
a second CRC generator configured to generate a local read CRC code associated with the read data based on the read data; and
a comparing circuit configured to compare the read CRC code and the local read CRC code to provide the decision signal.

7. The memory system of claim 1, wherein the memory device comprises:
a first CRC circuit configured to generate the read CRC code associated with read data based on the read data, configured to generate a first decision signal based on write data and a write CRC code associated with the write data, and configured to provide the first decision signal to a memory core unit;
a deserializer configured to separate the command/address packet into the command/address and the second CRC code; and
a second CRC circuit configured to generate a second decision signal based on the command/address, and configured to provide the second decision signal to the memory core unit.

8. The memory system of claim 7, wherein the first CRC circuit comprises:
a first CRC generator configured to generate the read CRC code based on the read data;
a second CRC generator configured to generate a local write CRC code associated with the write data based on the write data; and
a comparing circuit configured to compare the write CRC code and the local write CRC code to provide the first decision signal.

9. The memory system of claim 7, wherein the second CRC circuit comprises:
a CRC generator configured to generate a local second CRC code based on the command/address packet; and
a comparing circuit configured to compare the local second CRC code and the second CRC code to provide the second decision signal.

10. The memory system of claim 1, wherein one bit of the first CRC code corresponds to a plurality of bits of the data.

11. A memory system comprising:
a memory controller; and
a memory device configured to exchange data with the memory controller through differential signaling, wherein the memory device comprises:
a memory cell array that includes a normal cell array for storing the data and an error check and correction (ECC) cell array for storing an ECC code associated with the data; and
an ECC circuit configured to correct errors in the data stored in the normal cell array using the ECC code.

12. The memory system of claim 11, wherein the memory device further comprises an input/output (I/O) circuit, connected to the ECC circuit, configured to provide corrected data from the ECC circuit to the memory controller through the differential signaling.

13. The memory system of claim 12, wherein the ECC circuit comprises:
an encoder configured to encode write data, configured to provide the write data to the normal cell array, and configured to provide the ECC code to the ECC cell array; and
a decoder configured to decode read data, configured to correct errors in the read data, and configured to provide corrected read data to the I/O circuit.

14. The memory system of claim 13, wherein the decoder comprises:
an error detector configured to determine whether the read data have errors to provide a decision signal; and
an error corrector configured to correct the errors in the read data to provide the corrected read data to the I/O circuit, in response to the decision signal.

15. The memory system of claim 12, wherein the I/O circuit comprises:
an input buffer configured to select between the data and inverted data to provide the write data to the ECC circuit; and
an output buffer configured to provide the data and the inverted data based on the read data.

16. The memory system of claim 15, wherein the input buffer comprises:
a selection circuit that selects the data between the data and the inverted data in response to a selection signal; and
a latch circuit that latches the data to provide the write data.

17. The memory system of claim 15, wherein the output buffer comprises:
a first latch circuit that latches the read data to provide the data;
a data inversion unit that inverts the data; and
a second latch circuit that latches an output of the data inversion unit to provide the inverted data.

18. The memory system of claim 12, wherein the memory cell array is single-ended connected to the ECC circuit.

19. The memory system of claim 12, wherein the ECC circuit is single-ended connected to the I/O circuit.

20. A memory system comprising:
a memory controller; and
a memory device configured to exchange data with the memory controller through a first channel, configured to exchange a first cyclic redundancy check (CRC) code associated with the data with the memory controller through a second channel, and configured to receive from the memory controller through a third channel a command/address packet including a second CRC code associated with a command/address; wherein:
the memory controller comprises:
a first CRC circuit configured to receive read data, configured to generate a read CRC code associated with the read data, and configured to generate a decision signal based on write data and a write CRC code associated with the write data;
a second CRC circuit configured to generate the second CRC code in response to the command/address; and
a serializer configured to packetize the command/address and the second CRC code to provide a command/address packet; and
the memory device comprises:
a third CRC circuit configured to generate the read CRC code associated with read data based on the read data, configured to generate a second decision signal based on write data and a write CRC code associated with the write data, and configured to provide the second decision signal to a memory core unit;
a deserializer configured to separate the command/address packet into the command/address and the second CRC code; and
a fourth CRC circuit configured to generate a third decision signal based on the command/address, and configured to provide the third decision signal to the memory core unit.

21. The memory system of claim 20, wherein the first CRC circuit comprises:
a first CRC generator configured to generate the write CRC code based on the write data;
a second CRC generator configured to generate a local read CRC code associated with the read data based on the read data; and
a comparing circuit configured to compare the read CRC code and the local read CRC code to provide the decision signal.

22. The memory system of claim 20, wherein the third CRC circuit comprises:
a first CRC generator configured to generate the read CRC code based on the read data;
a second CRC generator configured to generate a local write CRC code associated with the write data based on the write data; and
a comparing circuit configured to compare the write CRC code and the local write CRC code to provide the first decision signal.

23. The memory system of claim 20, wherein the fourth CRC circuit comprises:
a CRC generator configured to generate a local second CRC code based on the command/address packet; and
a comparing circuit configured to compare the local second CRC code and the second CRC code to provide the second decision signal.

24. A method of controlling a memory device with a memory controller, the method comprising:
exchanging data between the memory device and the memory controller through a first channel;
exchanging a first cyclic redundancy check (CRC) code associated with the data between the memory device and the memory controller through a second channel; and
receiving at the memory device from the memory controller through a third channel a command/address packet including a second CRC code associated with a command/address.

25. The method of claim 24, further comprising separating the first, second and third channels from each other.

26. The method of claim 24, wherein the command/address packet further includes the command/address.

27. The method of claim 24, wherein the data is exchanged between the memory controller and the memory device in a packet format.
